(19) United States
(12) Patent Application Publication
(10) Pub. No.: US 2025/0323518 A1
(43) Pub. Date: Oct. 16, 2025

(54) TECHNIQUES FOR BATTERY STRING CONNECTION IN AN ELECTRIC MACHINE

(71) Applicant: Caterpillar Inc., Peoria, IL (US)

(72) Inventors: Keith N. Troisi, Dunlap, IL (US); Karthik Majjari, Dunlap, IL (US); Hua Xu, Dunlap, IL (US); Joseph Oluwagbeminiyi Oyekan, Cambridgeshire (GB); Alexander C. Crosman, III, Dunlap, IL (US)

(73) Assignee: Caterpillar Inc., Peoria, IL (US)

(21) Appl. No.: 18/631,631

(22) Filed: Apr. 10, 2024

(51) Int. Cl. H02J 7/00; G01R 31/388; G01R 31/392

(52) U.S. Cl. CPC H02J 7/0069; G01R 31/388; G01R 31/392; H02J 7/0013; H02J 7/00304

(57) ABSTRACT

Various techniques are described for initially bringing only a first subset of available batteries online, such as by initially pre-charging the system using only one battery string of a battery pack. Once the first subset of batteries is online, an electronic control module draws power from the first subset of batteries to pre-charge and then proceeds to bring one or more additional subsets of batteries online. These techniques improve the efficiency and functionality of battery systems by introducing a self-priming capability that reduces an initial current draw, thereby enhancing the operational flexibility and reducing the cost and complexity of the system.

### FIELD OF THE DISCLOSURE

This document relates generally to energy storage systems for electric machines.

### BACKGROUND

The management of energy storage systems, particularly those involving lithium-ion (Li-ion) batteries, is an important aspect of modern electrical engineering. Li-ion batteries are favored for their high energy density and efficiency, but they require careful handling and precise control mechanisms to maintain safety and longevity. A key component in this management process is the pre-charging phase, which is important for preparing the battery cells for the full engagement of power flow without causing damage to the system or batteries.

Pre-charging is a controlled method of initially charging the system at low current to equalize the system and battery voltages before fully connecting the batteries to the system. This process helps prevent inrush currents that may lead to excessive heat generation, component stress, and potential failure. Inrush currents may be particularly problematic as they may cause contactors within the power modules to weld shut, leading to permanent damage and safety hazards. Therefore, managing the pre-charge process is vital for the integrity and reliability of the battery system.

Another significant consideration in the design and operation of Li-ion battery systems is the initial current draw required to power up the control systems. These control systems, which include various electronic control modules and embedded software, are responsible for the safe and efficient operation of the battery pack. They may be powered up before the main energy storage is brought online. The magnitude of the initial current draw may have implications for the sizing of electrical components and the overall design of the system.

CN116247771A discloses an inverter activation lithium battery device with a protection function and a control method thereof. An inverter lithium battery activation device comprises a main circuit, a lithium battery activation circuit, a power grid auxiliary power supply, a battery auxiliary power supply, a relay circuit and a microprocessor, a group of power grid input GRID is connected to the power grid auxiliary power supply, and the power grid auxiliary power supply is used for supplying power to the battery auxiliary power supply and providing an activation source for the lithium battery activation circuit. The battery auxiliary power supply is used for supplying power to the microprocessor and the main circuit, the activation source is connected to the lithium battery through the lithium battery activation circuit, the other group of power grid input GRID is divided into two paths of output after passing through the relay circuit, one path of output is connected to the alternating current output, the other path of output is connected to the main circuit, and one end of the main circuit is connected to the lithium battery. The lithium battery activation circuit is combined with the auxiliary power supply to independently control the lithium battery activation function, so that the charging management is more intelligent, and the system operation is more stable.

### SUMMARY OF THE DISCLOSURE

This disclosure describes various techniques for initially bringing only a first subset of available batteries online, such as by initially pre-charging the system using only one battery string of a battery pack. Once the first subset of batteries is online, an electronic control module draws power from the first subset of batteries to pre-charge and then proceeds to bring one or more additional subsets of batteries online. These techniques improve the efficiency and functionality of battery systems by introducing a self-priming capability that reduces an initial current draw, thereby enhancing the operational flexibility and reducing the cost and complexity of the system.

In some aspects, this disclosure is directed to an electrical system having an output configured for supplying electrical power to an electric machine, the electrical system comprising: a plurality of battery strings, wherein each battery string includes a battery module having at least one battery cell; a pre-charge circuit coupled with the plurality of battery strings; and an electronic control module configured for: determining a state of charge of each of the battery strings of the plurality of battery strings; selecting, based on the state of charge, the subset of the plurality of battery strings; coupling, via the pre-charge circuit, the selected subset of the plurality of battery strings with the output of the electrical system so as to reduce an inrush current; and coupling, after coupling the selected subset of the plurality of battery strings with the output of the electrical system, the remaining ones of the plurality of battery strings with the output of the electrical system.

In some aspects, this disclosure is directed to a method for reducing an inrush current for an electrical system of an electric machine having a plurality of battery strings, wherein each battery string includes a battery module having at least one battery cell, the method comprising: determining a state of charge of each of the battery strings of the plurality of battery strings; selecting, based on the state of charge, the subset of the plurality of battery strings; coupling, via a pre-charge circuit, the selected subset of the plurality of battery strings with an output of the electrical system so as to reduce an inrush current; and coupling, after coupling the selected subset with the output of the electrical system, the remaining ones of the plurality of battery strings with the output of the electrical system.

In some aspects, this disclosure is directed to an electrical system having an output configured for supplying electrical power to an electric machine, the electrical system comprising: a plurality of battery strings, wherein each battery string includes a battery module having at least one battery cell; a pre-charge circuit coupled with the plurality of battery strings; and an electronic control module configured for: determining a state of charge of each of the battery strings of the plurality of battery strings; selecting, based on the state of charge, the subset of the plurality of battery strings; coupling, via the pre-charge circuit, the selected subset of the plurality of battery strings with the output of the electrical system so as to reduce an inrush current, wherein the selected subset of the plurality of battery strings supplies power to the electronic control module; and coupling, after coupling the selected subset of the plurality of battery strings with the output of the electrical system, the remaining ones of the plurality of battery strings with the output of the electrical system, wherein the selected subset of the plurality of battery strings supplies additional power to the electronic control module.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a perspective view of an example of an electric machine (at least partially battery powered) that can implement various techniques of this disclosure.

FIGS. 2A-2B depict a block diagram of an example of an electrical system that can implement various techniques of this disclosure.

FIG. 3 depicts a simplified block diagram of a battery system that can implement various techniques of this disclosure.

FIG. 4 is a flow diagram of an example of a method for reducing an inrush current for an electrical system of an electric machine having a plurality of battery strings, where each battery string includes a battery module having at least one battery cell.

### DETAILED DESCRIPTION

Traditionally, auxiliary power sources, such as lead-acid batteries, have been used to supply the necessary power to the control systems during startup. However, this approach can add complexity to the system, increase costs, and introduce additional points of potential failure. As such, there is a growing need for innovative solutions that can streamline the power-up process, reduce the initial current draw, and enhance the overall efficiency of Li-ion battery systems.

The industry continues to explore advancements in battery technology and control strategies to address these challenges. The present inventors have recognized that by optimizing the pre-charge process and minimizing the initial current draw, the performance and reliability of Li-ion battery systems can be improved, which are increasingly central to a wide range of applications, from consumer electronics to industrial machinery and renewable energy storage.

This disclosure describes various techniques for initially bringing only a first subset of available batteries online, such as by initially pre-charging the system using only one battery string of a battery pack. Once the first subset of batteries is online, an electronic control module draws power from the first subset of batteries to pre-charge and then proceeds to bring one or more additional subsets of batteries online. These techniques improve the efficiency and functionality of battery systems by introducing a self-priming capability that reduces an initial current draw, thereby enhancing the operational flexibility and reducing the cost and complexity of the system.

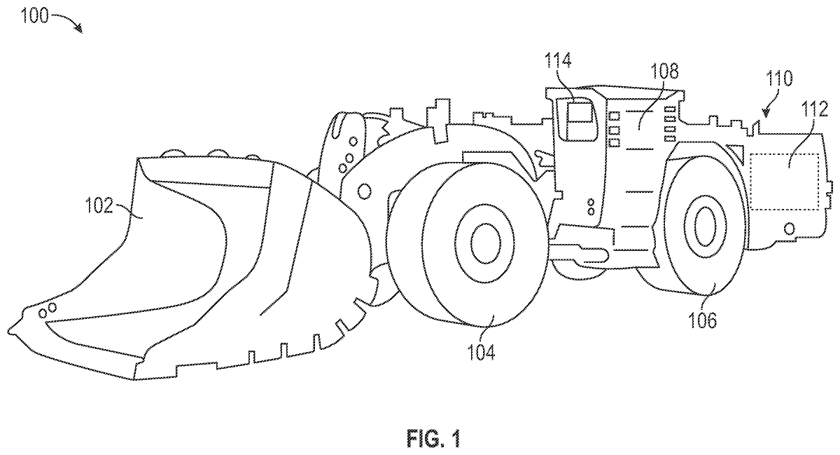

FIG. 1 is a perspective view of an example of an electric machine 100 (at least partially battery powered) that can implement various techniques of this disclosure. FIG. 1 depicts a non-limiting view of an electric machine 100 in the form of a load-haul-dump (LHD) vehicle, such as for mining, including a dump bucket 102, wheels 104, 106, an operator control cabin 108, and a vehicle body 110. The wheels 104, 106 are examples of traction components. In other examples, the electric machine 100 can include traction components such as one or more tracks, in addition to or instead of the wheels.

The electric machine 100, e.g., an electric mine truck, also includes an electrical system 112. The electrical system 112 can include a DC power source, including but not limited to one or more battery strings, which can supply power to, among other things, an electric motor. The electric motor can supply rotational power to one or more systems, such as a system configured to operate various hydraulics of the dump bucket 102. The electrical system 112 can supply power to at least one traction component, such as the wheel 104, 106, and to at least one accessory component 114, such a pump motor, fan, and the like. In some examples, the electric machine 100 can include electric vehicles, such as cars, trucks, motorcycles, buses, and the like.

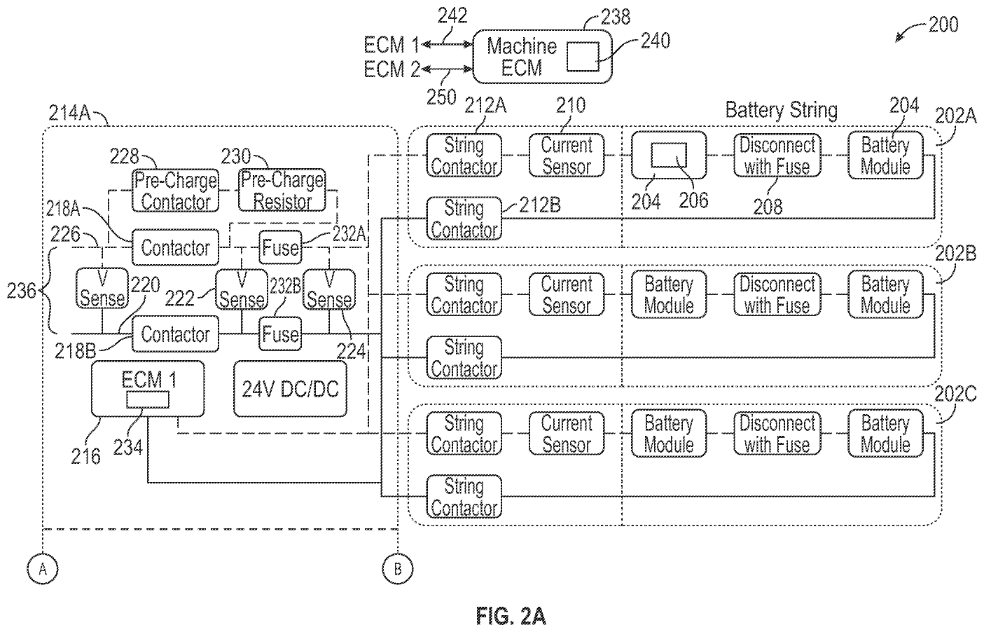

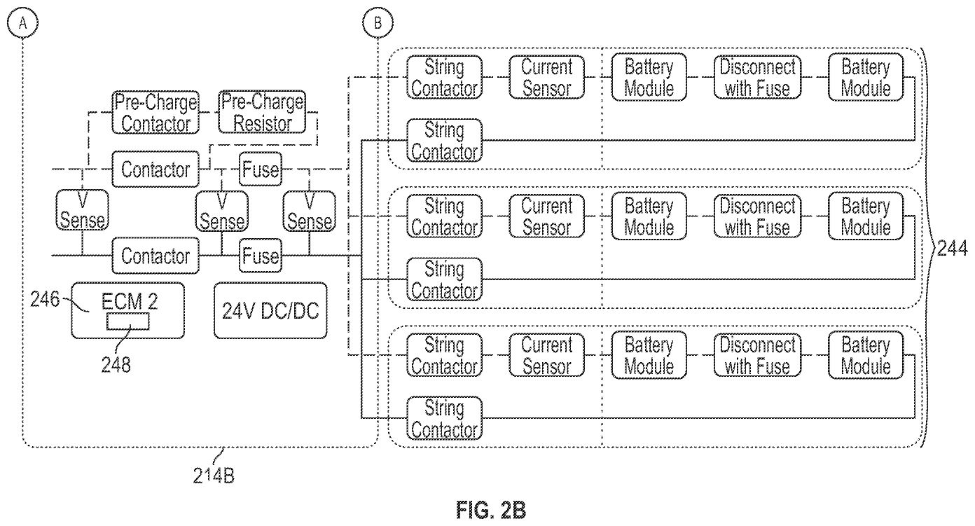

FIGS. 2A-2B depict a block diagram of an example of a battery system 200 that can implement various techniques of this disclosure. The battery system 200 forms part of the electrical system 112 of FIG. 1. The battery system 200 is configured to supply power to one or more components of an electric machine, such as at least one traction component and/or at least one accessory component of the electric machine 100 of FIG. 1.

The battery system 200 includes a battery pack having a plurality of battery strings, such as three battery strings 202A-202C. In some examples, there can be more than three battery strings and in other examples, there can be two battery strings. Each battery string includes one or more battery modules 204 having at least one battery cell 206. Battery modules can be joined in series via an electrical disconnect 208, such as a fuse. Each battery string, such as the battery string 202A, can include a current sensor 210 configured for generating current data, which can be used to monitor the current through the battery string. The battery strings 202B and 202C can be similarly configured, as shown in FIGS. 2A-2B.

The plurality of battery strings 202A-202C can further include string contactors 212A, 212B so as to allow individual ones of the plurality of battery strings to be selectively electrically coupled with or electrically decoupled from a power module 214A. The power module 214A can include an electronic control module 216 (or ECM 216). The ECM 216 performs various functions to manage the battery system 200, as described below.

The power module 214A can also include pack contactors 218A, 218B, which can electrically disconnect all of the battery strings 202A-202C. The power module 214A can also include one or more voltage sensors 220-224 to monitor the voltages per battery string and on the electrical bus 226 and generate voltage data. The power module 214A can further include a pre-charge circuit coupled with the battery strings 202A-202C. The pre-charge circuit includes a pre-charge contactor 228 and a pre-charge resistor 230 that can be used to control the in-rush current as the battery strings are connected. The power module 214A can further include fuses 232A, 232B to permanently isolate the power module 214A from the plurality of battery strings 202A-202C.

Each sensor, such as the voltage sensor 224 and the current sensor 210, can be configured to monitor an electrical parameter of at least one battery string of the plurality of battery strings, such as voltage and current, respectively. Temperature sensors can be included to detect temperature. The voltage, current, and temperature can be referred to as operational data.

The ECM 216 collects operational data from the battery module, e.g., at least one of temperature, voltage, and current. Using the operational data, the ECM 216 determines a state of charge (SOC) of one or more of the battery cells 212. The SOC of a battery cell (or a battery string) in a battery module 114 can be defined as the available capacity (in Ah) and expressed as a percentage of its rated capacity. The SOC parameter can be viewed as a thermodynamic quantity enabling one to assess the potential energy of a battery. The SOC parameter of a battery decreases over time as energy is drawn from the battery.

One technique for estimating the SoC of a battery string involves utilizing a voltage measurement technique. This technique is predicated on the correlation between a battery string's voltage and its SoC, where a higher voltage typically indicates a higher SoC. The process includes measuring the battery string's terminal voltage and comparing it to a reference curve or table that specifically relates voltage levels to SoC percentages for the battery type in question.

Another technique for determining the SoC of a battery string is known as Coulomb counting, or the Ampere-Hour method. This approach quantifies the electrical charge transferred into or out of the battery string over time, effectively tracking the cumulative amount of charge (in coulombs) to deduce the change in SoC. To implement Coulomb counting, an initial SoC value is established. The method then involves the continuous integration of current flow into or out of the battery, converting this integrated charge into a percentage of the battery's total capacity to update the SoC estimation.

For enhanced accuracy and reliability in SoC estimation, hybrid techniques that combine the principles of voltage-based estimation and Coulomb counting may be used. These hybrid approaches leverage the advantages of each method, utilizing voltage measurements for their simplicity and Coulomb counting for its capability to track actual charge flow. By integrating these methodologies, a more robust and dynamic system for SoC estimation is achieved, capable of adapting to varying operational conditions and mitigating the limitations inherent in each individual approach.

In some examples, the ECM 216 computes the state of health of one or more of the battery strings. The state of health (SOH) of a battery cell (or a battery string) represents a measure of the battery cell's ability to store and deliver electrical energy compared with a new battery. A decline in the SOH of a battery can cause a battery to discharge faster. A battery's internal impedance is an example of a battery characteristic that corresponds well with its SOH and that can be measured periodically to monitor the battery. The ECM 216 is configured to receive the operational data for each battery string 202A-202C.

The ECM 216 is electrically coupled to the battery system 200 and is configured to receive the sensed signals, e.g., voltage and current, and output control signals, such as to control the opening and closing of various contactors.

The electrical system 112 of FIG. 1 can include an output 236 coupled to the electrical system 200, such as at the electrical bus 226, which is configured to supply the electrical power to the accessory component(s), e.g., fans, pump motors for hydraulics and/or cooling, etc., without supplying power to the traction component(s), e.g., wheels and/or tracks.

The electrical system 112 of the electric machine 100 of FIG. 1 can further include a machine ECM 238. The ECM 238 can include a control unit 240 and the ECM 238 is in electrical communication with the ECM 216 via communication path 242.

The electrical system 200 of FIGS. 2A-2B can include one or more additional battery strings, such as the plurality of battery strings 244, which is similar to the battery strings 202A-202C and, for brevity, will not be described again in detail. The electrical system 200 can include a power module 214B electrically coupled with the plurality of battery strings 244. The power module 214B is similar to the power module 214A and, for brevity, will not be described again in detail. The power module 214B can include an ECM 246 having a control unit 248. The ECM 246 performs various functions to manage the electrical system 200, as described in this disclosure with respect to ECM 216. The ECM 246 is in electrical communication with the machine ECM 238 via communication path 250. Other examples can include more battery strings and corresponding ECMs.

As described in more detail below, this disclosure describes a self-priming capability that reduces an initial current draw, thereby enhancing the operational flexibility and reducing the cost and complexity of the system. For example, the ECM 216 initially brings only a first subset of available batteries online, such as by initially pre-charging only one battery string of a battery pack, e.g., the battery string 202A. Once the first subset of batteries is online, the ECM 216 draws power from the first subset of batteries, e.g., the battery string 202A, to pre-charge any additional subsets of batteries and bring a full voltage bus online, e.g., battery strings 202B, 202C.

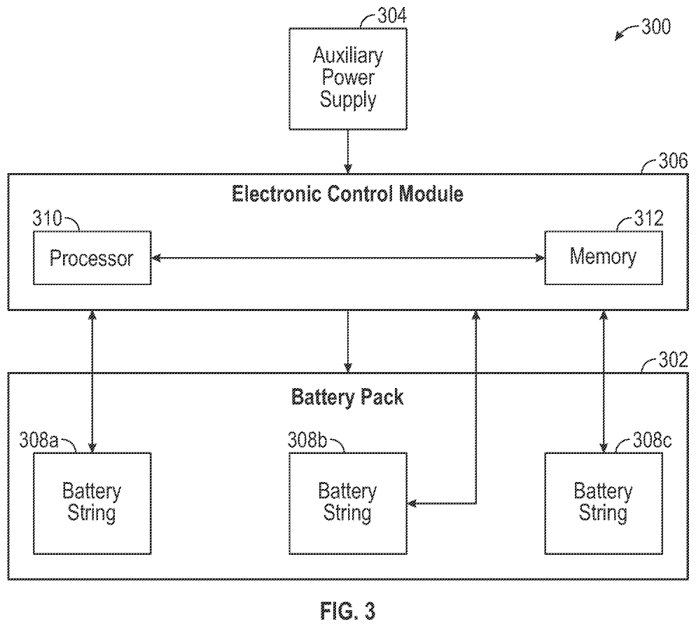

FIG. 3 depicts a simplified block diagram of a battery system 300 that can implement various techniques of this disclosure. The battery system 300 is a simplified version of the battery system 200 shown in FIGS. 2A and 2B, which forms part of the electrical system 112 of FIG. 1.

The battery system 300 includes a battery pack 302, which includes two or more battery strings, such as battery string 308a, battery string 308b, and battery string 308c. The battery strings 308a-308c can be similar to the battery strings 202A-202C of FIG. 2A, for example.

The battery system 300 includes an auxiliary power supply 304 configured for supplying only enough power to an electronic control module 306 to allow the electronic control module 306 minimum functionality, such as wake up power. The electronic control module 306 is similar to the ECM 216 of FIG. 2A and the ECM 246 of FIG. 2B. As described below, the electronic control module 306 will select a battery string to bring online, which will supply additional (but not full) power to the electronic control module 306. The auxiliary power supply 304 is configured for providing an initial power to the electronic control module sufficient to permit the electronic control module to select the subset of the plurality of battery strings and couple, via the pre-charge circuit, the selected subset of the plurality of battery strings with the output of the electrical system. The electronic control module 306 will then bring the remaining battery strings online, which will supply further power to the electronic control module 306 so it is operating with its full functionality.

By using the techniques of this disclosure, the auxiliary power supply 304, e.g., a lead acid battery, can be sized to deliver a small percentage of a maximum power draw of the electronic control module 306. The auxiliary power supply 304 can be on or off board the electric machine 100 of FIG. 1 or the battery pack 302.

By way of a non-limiting example, if the electronic control module 306 requires 10 amps of current for full functionality, the auxiliary power supply 304 can be sized to deliver a fraction of that current, such as 2 amps. The small percentage of maximum current draw, e.g., 2 amps, is sufficient to power up a minimum amount of circuitry in the electronic control module 306, such as a processor 310 in communication with a memory 312, to control various components in FIG. 2A, for example, to initially bring only a subset of available battery strings online, such as by initially pre-charging only one battery string of a battery pack 302. Once the subset of batteries is online, the electronic control module 306 draws power from the subset of batteries to pre-charge any additional subsets of batteries and bring a voltage bus online, such as the electrical bus 226 of FIG. 2A.

For example, the electronic control module 306 determines a state of charge of each of the battery strings of the plurality of battery strings and selects, based on the state of charge, the battery string 308a. For example, the electronic control module 306 selects the battery string, e.g., the battery string 308a, with the highest state of charge. The electronic control module 306 outputs signals to control the string contactors 212A, 212B of FIG. 2A to close so as to couple the battery string 308a, via the pre-charge circuit of FIG. 2A that includes the pre-charge contactor 228 and the pre-charge resistor 230, with the output 236 of FIG. 2A so as to reduce an inrush current. The selected subset of the plurality of battery strings, e.g., the battery string 308a, supplies additional power to the electronic control module 306 beyond that supplied by the auxiliary power supply 304.

Then, after coupling the battery string 308a with the output 236, the electronic control module 306 outputs signals to couple the remaining ones of the battery strings, e.g., the battery string 308b and the battery string 308c, with the output 236. For example, the electronic control module 306 outputs signals to control the string contactors associated with the battery strings 202B, 202C of FIG. 2A to close so as to couple those battery strings to the output 236 of the electrical system, e.g., the electrical system 112 of FIG. 1. These remaining strings supply additional power to the electronic control module 306 thereby allowing the electronic control module 306 to power up any of its remaining circuitry so as to enable its fully functionality.

In some examples, the battery system 300 includes a sensor coupled with the electronic control module 306 and configured for monitoring an electrical parameter of at least one battery string of the plurality of battery strings. For example, the battery system 300 can include a current sensor and/or a voltage sensor, such as the current sensor 210 of FIG. 2A and/or the voltage sensor 224 of FIG. 2A. The electronic control module is configured for receiving data representing the electrical parameter from the sensor, and determining, based on the data, which subset to select of the plurality of battery strings.

In some examples, the electronic control module 306 configured for determining, based on the data, the selected subset of the plurality of battery strings is configured for determining a state of health of each of the battery strings of the plurality of battery strings, and then selecting, based on the state of health, the subset of the plurality of battery strings. For example, the electronic control module 306 selects the battery string with the highest state of health.

In other examples, the electronic control module 306 is configured for determining a state of health of each of the battery strings of the plurality of battery strings and determining a state of charge of each of the battery strings of the plurality of battery strings, and then selecting, based on both the state of health and the state of charge, the subset of the plurality of battery strings. For example, the electronic control module 306 can apply weights to the state of charge and the state of health, determine a resulting score, and select the battery string with the highest score.

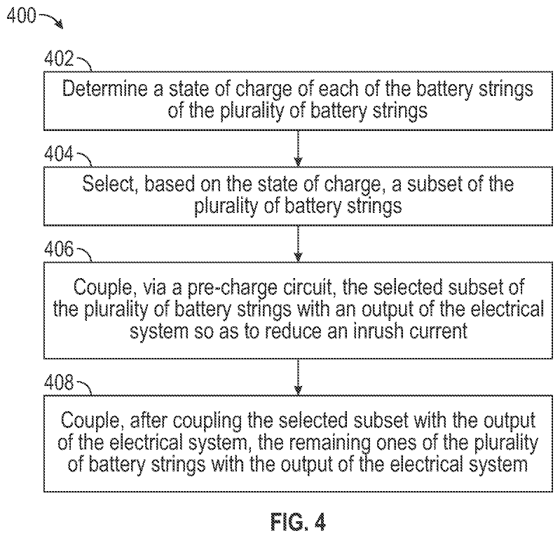

FIG. 4 is a flow diagram of an example of a method 400 for reducing an inrush current for an electrical system of an electric machine having a plurality of battery strings, where each battery string includes a battery module having at least one battery cell. At block 402, the method includes determining a state of charge of each of the battery strings of the plurality of battery strings. For example, the electronic control module selects the battery string with the highest state of charge.

At block 404, the method 400 includes selecting, based on the state of charge, a subset of the plurality of battery strings.

At block 406, the method 400 includes coupling, via a pre-charge circuit, the selected subset of the plurality of battery strings with an output of the electrical system so as to reduce an inrush current.

At block 408, the method 400 includes coupling, after coupling the selected subset with the output of the electrical system, the remaining ones of the plurality of battery strings with the output of the electrical system.

In some examples, the method 400 includes monitoring an electrical parameter of at least one battery string of the plurality of battery strings, and receiving data representing the electrical parameter. In some examples, the data includes voltage data and/or current data.

In some examples, the method 400 includes determining a state of health of each of the battery strings of the plurality of battery strings. In some examples, the electronic control module uses both the state of charge and the state of health to select the subset of the plurality of battery strings.

In some examples, the method 400 includes supplying, via the selected subset of the plurality of battery strings, power to the electronic control module.

In some examples, the method 400 includes supplying, via an auxiliary power supply, an initial power to an electronic control module sufficient to permit the electronic control module to select the subset of the plurality of battery strings and couple, via the pre-charge circuit, the selected subset of the plurality of battery strings with the output of the electrical system.

### INDUSTRIAL APPLICABILITY

The industrial applicability of the present invention is extensive and multifaceted, addressing critical needs in various sectors where battery systems are employed, such as lithium-ion (Li-ion) battery systems. The invention's innovative approach to managing the power-up sequence of battery packs has direct implications for industries such as electric vehicles, renewable energy storage, and heavy machinery, including those used in construction and mining operations.

In the electric machine industry, the invention's ability to selectively activate a subset of the battery pack to initiate the power-up sequence can significantly enhance the vehicle's operational readiness. This is particularly beneficial for electric machines that require a rapid start-up sequence and efficient energy management to extend the driving range and reduce downtime during charging cycles. The invention's strategy for minimizing initial current draw can also contribute to the longevity of the battery pack.

In the realm of heavy machinery, particularly in sectors like construction and mining, the invention's control strategy can facilitate the use of Li-ion battery systems in a more efficient and cost-effective manner. The ability to power up the BMS and the battery pack without the need for a separate lead-acid battery can simplify the machine's design, reduce weight, and improve reliability. This is especially relevant for machinery that operates in remote or harsh environments where reliability and ease of maintenance are paramount.

Furthermore, the invention's approach to pre-charging and controlling the initial current draw can lead to smaller and more efficient electrical components, reducing the overall footprint and weight of the energy storage system. This can result in significant cost savings in terms of materials and logistics, as well as improved performance due to the reduced mass of the system.

### Various Notes

Each of the non-limiting claims or examples described herein may stand on its own, or may be combined in various permutations or combinations with one or more of the other examples.

The above detailed description includes references to the accompanying drawings, which form a part of the detailed description. The drawings show, by way of illustration, specific embodiments in which the invention may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more claims thereof), either with respect to a particular example (or one or more claims thereof), or with respect to other examples (or one or more claims thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact discs and digital video discs), magnetic cassettes, memory cards or sticks, random access memories (RAMs), read only memories (ROMs), and the like.

The above description is intended to be illustrative, and not restrictive. For example, the above-described examples (or one or more claims thereof) may be used in combination with each other. Other embodiments may be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments may be combined with each other in various combinations or permutations. The scope of the invention should be determined with reference to the appended claims, along with the full scope of equivalents to which such claims are entitled.

What is claimed is:

1. An electrical system having an output configured for supplying electrical power to an electric machine, the electrical system comprising:
a plurality of battery strings, wherein each battery string includes a battery module having at least one battery cell;
a pre-charge circuit coupled with the plurality of battery strings; and
an electronic control module configured for:
determining a state of charge of each of the battery strings of the plurality of battery strings;
selecting, based on the state of charge, a subset of the plurality of battery strings;
coupling, via the pre-charge circuit, the selected subset of the plurality of battery strings with the output of the electrical system so as to reduce an inrush current; and
coupling, after coupling the selected subset of the plurality of battery strings with the output of the electrical system, the remaining ones of the plurality of battery strings with the output of the electrical system.

2. The electrical system of claim 1, comprising:
a sensor coupled with the electronic control module and configured for monitoring an electrical parameter of at least one battery string of the plurality of battery strings,
wherein the electronic control module is configured for:
receiving, from the sensor, data representing the electrical parameter.

3. The electrical system of claim 2, wherein the sensor includes a voltage sensor, and wherein the data includes voltage data.

4. The electrical system of claim 2, wherein the sensor includes a current sensor, and wherein the data includes current data.

5. The electrical system of claim 2, wherein the electronic control module is configured for:
determining a state of health of each of the battery strings of the plurality of battery strings.

6. The electrical system of claim 1, wherein the selected subset of the plurality of battery strings supplies power to the electronic control module.

7. The electrical system of claim 1, comprising:
an auxiliary power supply coupled with the electronic control module and configured for supplying an initial power to the electronic control module sufficient to permit the electronic control module to select the subset of the plurality of battery strings and couple, via the pre-charge circuit, the selected subset of the plurality of battery strings with the output of the electrical system.

8. A method for reducing an inrush current for an electrical system of an electric machine having a plurality of battery strings, wherein each battery string includes a battery module having at least one battery cell, the method comprising:
determining a state of charge of each of the battery strings of the plurality of battery strings;
selecting, based on the state of charge, a subset of the plurality of battery strings;
coupling, via a pre-charge circuit, the selected subset of the plurality of battery strings with an output of the electrical system so as to reduce an inrush current; and
coupling, after coupling the selected subset with the output of the electrical system, the remaining ones of the plurality of battery strings with the output of the electrical system.

9. The method of claim 8, comprising:
monitoring an electrical parameter of at least one battery string of the plurality of battery strings; and
receiving data representing the electrical parameter.

10. The method of claim 9, wherein the data includes voltage data.

11. The method of claim 9, wherein the data includes current data.

12. The method of claim 9, comprising:
determining a state of health of each of the battery strings of the plurality of battery strings.

13. The method of claim 9, comprising:
supplying, via the selected subset of the plurality of battery strings, power to an electronic control module.

14. The method of claim 9, comprising:
supplying, via an auxiliary power supply, an initial power to an electronic control module sufficient to permit the electronic control module to select the subset of the plurality of battery strings and couple, via the pre-charge circuit, the selected subset of the plurality of battery strings with the output of the electrical system.

15. An electrical system having an output configured for supplying electrical power to an electric machine, the electrical system comprising:
a plurality of battery strings, wherein each battery string includes a battery module having at least one battery cell;
a pre-charge circuit coupled with the plurality of battery strings; and
an electronic control module configured for:
determining a state of charge of each of the battery strings of the plurality of battery strings;
selecting, based on the state of charge, a subset of the plurality of battery strings;
coupling, via the pre-charge circuit, the selected subset of the plurality of battery strings with the output of the electrical system so as to reduce an inrush current, wherein the selected subset of the plurality of battery strings supplies power to the electronic control module; and
coupling, after coupling the selected subset of the plurality of battery strings with the output of the electrical system, the remaining ones of the plurality of battery strings with the output of the electrical system, wherein the selected subset of the plurality of battery strings supplies additional power to the electronic control module.

16. The electrical system of claim 15, comprising:
a sensor coupled with the electronic control module and configured for monitoring an electrical parameter of at least one battery string of the plurality of battery strings,
wherein the electronic control module is configured for:
receiving, from the sensor, data representing the electrical parameter.

17. The electrical system of claim 15, wherein the electronic control module is configured for:
determining a state of health of each of the battery strings of the plurality of battery strings.
